(19) United States
(12) Patent Application Publication
(10) Pub. No.: US 2006/0202216 A1
(43) Pub. Date: Sep. 14, 2006

(54) Semiconductor light emitting device, semiconductor light emitting apparatus, and method of manufacturing a semiconductor light emitting device

(75) Inventor: Shuji Itonaga, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/359,371

(22) Filed: Feb. 23, 2006

(30) Foreign Application Priority Data
Mar. 8, 2005 (JP) 2005-063400

(51) Int. Cl. H01L 33/00

(52) U.S. Cl. 257/94

(57) ABSTRACT

A semiconductor light emitting device comprises: a semiconductor multilayer structure; and an aluminum nitride layer. The semiconductor multilayer structure includes a light emitting layer that emits a light. The aluminum nitride layer is provided on a surface of the semiconductor multilayer structure. The aluminum nitride layer has asperities with an average pitch of not more than half an in-medium wavelength of the light in aluminum nitride. Alternatively, the semiconductor light emitting device may have asperities composed of a plurality of protrusions including the aluminum nitride layer and a plurality of depressions intruding into the semiconductor multilayer structure.

### CROSS-REFERENCE TO RELATED APPLICATIONS

This application is based upon and claims the benefits of priorities from the prior Japanese Patent Application No. 2005-063400, filed on Mar. 8, 2005; the entire contents of which are incorporated herein by reference.

### BACKGROUND OF THE INVENTION

1. Field of the Invention

This invention relates to a semiconductor light emitting device, a semiconductor light emitting apparatus, and a method of manufacturing a semiconductor light emitting device, and more particularly to a semiconductor light emitting device with improved external light extraction efficiency, a semiconductor light emitting apparatus based thereon, and a method of manufacturing this semiconductor light emitting device.

2. Background Art

There is a continuing demand for semiconductor light emitting apparatuses with high brightness and high external extraction efficiency for use in backlights of liquid crystal displays, push button lamps of mobile phones, car dashboard displays, and traffic lights. In these semiconductor light emitting apparatuses, a semiconductor light emitting device (hereinafter referred to as LED) is mounted within a package, which is filled with sealing resin to cover the LED chip. An epoxy-based resin or silicone resin, for example, is often used for the sealing resin.

Epoxy-based resin has a refractive index of about 1.5. On the other hand, in the LED, an InGaAIP-based material is primarily used for the visible band, whereas a GaN-based material is primarily used for the wavelength bands of ultraviolet to blue light. InGaAIP has a refractive index of about 3.3, and GaN has a refractive index of about 2.5. The large difference of refractive index relative to epoxy-based resin causes reflection at the interface and total reflection in accordance with Snell's law. As a result, in particular, the external light extraction efficiency at the upper face of the LED is decreased.

In this respect, a structure has been proposed that provides fine asperities on the LED surface to reduce total reflection, thereby improving the external extraction efficiency (e.g., JP 2003-209283A). In this structure, while the asperities have a fine pitch, reflection and refraction of light obeys geometrical optics, which treats light as a light flux that travels in a straight line. In this case, since a light flux is emitted with wider angles at the asperity cross section, the angle range for total reflection is narrowed, thereby improving the light extraction efficiency. However, the limitations of fine patterning processes make it extremely difficult to sufficiently decrease the asperity pitch relative to half the wavelength.

More specifically, in the above example, electron beams (EB) or X-rays are used to delineate a fine etching mask, which is used in turn to form a fine asperity pattern. This is a sophisticated and complex process, involving problems in uniformity, productivity, and reproducibility of characteristics.

### SUMMARY OF THE INVENTION

According to an aspect of the invention, there is provided a semiconductor light emitting device comprising:
a semiconductor multilayer structure including a light emitting layer that emits a light; and
an aluminum nitride layer provided on a surface of the semiconductor multilayer structure, the aluminum nitride layer having asperities with an average pitch of not more than half an in-medium wavelength of the light in aluminum nitride.

According to other aspect of the invention, there is provided a semiconductor light emitting device comprising:
a semiconductor multilayer structure including a light emitting layer that emits light; and
an aluminum nitride layer provided on a surface of the semiconductor multilayer structure,
the semiconductor light emitting device having asperities composed of a plurality of protrusions including the aluminum nitride layer and a plurality of depressions intruding into the semiconductor multilayer structure.

According to other aspect of the invention, there is provided a semiconductor light emitting apparatus comprising:
a packaging member;
a semiconductor light emitting device mounted on the packaging member; and
a sealing resin sealing the semiconductor light emitting device,
the semiconductor light emitting device having:
   a semiconductor multilayer structure including a light emitting layer that emits a light; and
   an aluminum nitride layer provided on a surface of the semiconductor multilayer structure, the aluminum nitride layer having asperities with an average pitch of not more than half an in-medium wavelength of the light in aluminum nitride,
or
the semiconductor light emitting device having:
   a semiconductor multilayer structure including a light emitting layer that emits light; and
   an aluminum nitride layer provided on a surface of the semiconductor multilayer structure,
   the semiconductor light emitting device having asperities composed of a plurality of protrusions including the aluminum nitride layer and a plurality of depressions intruding into the semiconductor multilayer structure.

According to other aspect of the invention, there is provided a method of manufacturing a semiconductor light emitting device comprising:
forming a polycrystalline aluminum nitride layer on a surface of a semiconductor multilayer structure including a light emitting layer; and
etching the aluminum nitride layer to form asperities that generally correspond to distribution of crystal grains constituting the polycrystal.

### BRIEF DESCRIPTION OF THE DRAWINGS

FIG. 1 is a schematic view illustrating the overall structure of a semiconductor light emitting apparatus in a first example of the invention.

FIG. 2A is a schematic view illustrating a cross-sectional structure of an LED 5 provided in the example of the invention.

FIG. 2B is a schematic view illustrating a cross-sectional structure of another LED 5 provided in the example of the invention.

FIG. 2C is a schematic view illustrating a cross-sectional structure of another LED 5 provided in the example of the invention.

FIG. 3 is enlarged cross section of the aluminum nitride layer 12.

FIG. 4 is a graphical diagram illustrating the relation of the effective refractive index N to the distance X.

FIG. 5 is a process cross section illustrating the relevant part of a process of manufacturing a semiconductor light emitting apparatus in the example of the invention.

FIG. 6 is a TEM (transmission electron microscopy) photograph showing an example cross section of the AIN film 11 after being formed.

FIG. 7 is a process cross section illustrating the relevant part of a process of manufacturing a semiconductor light emitting apparatus in the example of the invention.

FIG. 8 is a SEM (scanning electron microscopy) photograph showing an example cross section of the AIN layer 12 after RIE.

FIG. 9 is a cross section showing the LED 5 being mounted in a package.

FIG. 10 is a schematic view showing a cross-sectional structure of an LED in a second example of the invention.

FIG. 11 is a schematic view illustrating asperities formed in the current diffusion layer 14 and the AIN layer 12.

FIG. 12 is a graphical diagram illustrating the variation of effective refractive index in the asperity portion.

FIG. 13 is a schematic view showing a cross-sectional structure of an LED in a third example of the invention.

FIG. 14 is a process cross section illustrating part of a process of manufacturing an LED in this example.

FIG. 15 is a schematic view illustrating asperities formed in the current diffusion layer 14.

FIG. 16 is a graphical diagram illustrating the variation of effective refractive index in the asperity portion.

### DETAILED DESCRIPTION OF THE INVENTION

Embodiments of the invention will now be described with reference to the drawings.

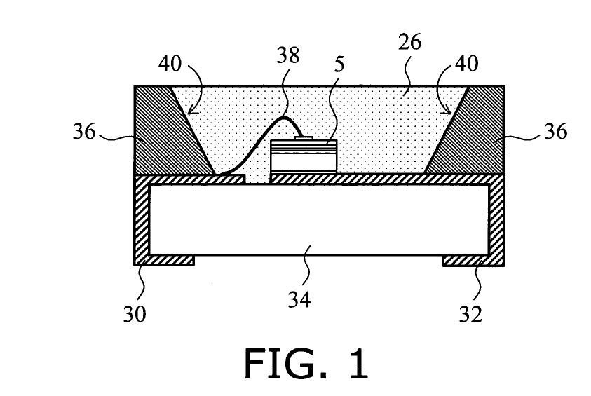

FIG. 1 is a schematic view illustrating the overall structure of a semiconductor light emitting apparatus in a first example of the invention.

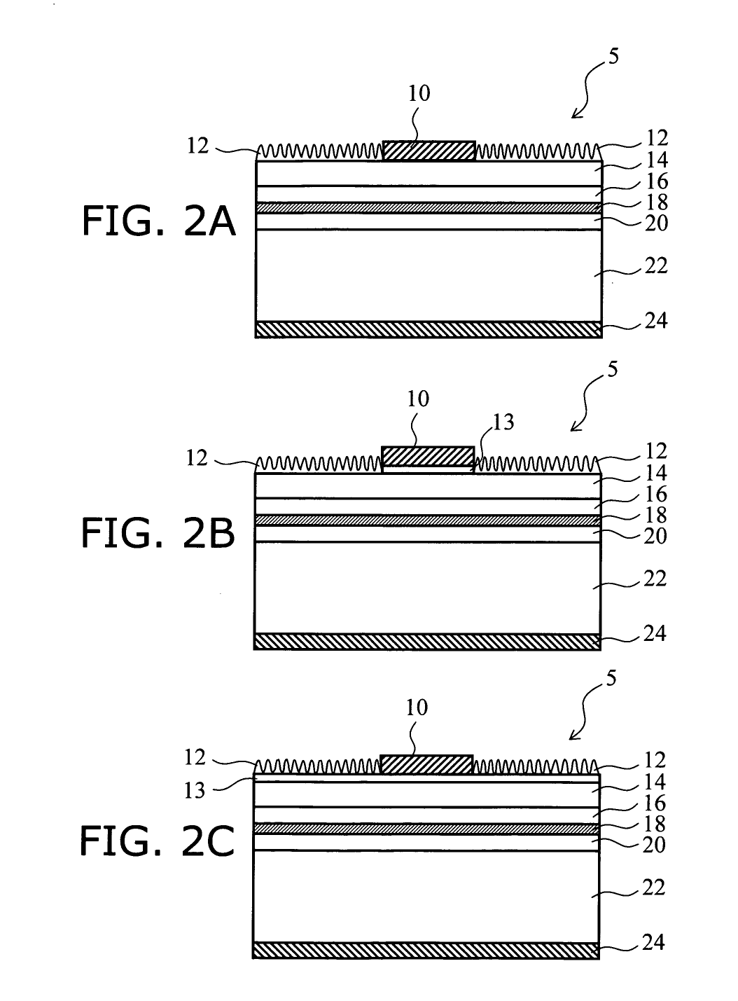

FIGS. 2A through 2C are schematic views illustrating cross-sectional structures of LED 5 provided in this example.

The semiconductor light emitting apparatus shown in FIG. 1 is first described. An LED 5 is mounted on a first lead 32 with an adhesive (not shown) such as gold-tin (AuSn) or other metal eutectic solder or silver paste. The LED 5 is connected to a second lead 30 via a bonding wire 38. The first lead 32 and the second lead 30 are embedded in, for example, an embedding resin 34. Furthermore, a resin 36 is provided to surround the LED 5. The LED 5 and the bonding wire 38 are sealed with a sealing resin 26. A portion of light emission from the LED 5 is directly released upward, and another portion of light emission is reflected from a reflecting film 40 provided on the resin 36 and emitted upward.

Next, the structure of the LED 5 is described.

As illustrated in FIG. 2A, on a substrate 22 is provided a semiconductor multilayer structure in which a cladding layer 20, an active layer (light emitting layer) 18, a cladding layer 16, and a current diffusion layer 14 are laminated. A top electrode 10 is formed on part of the top of the current diffusion layer 14, and a bottom electrode 24 is formed on the bottom of the substrate 22. For example, the cladding layers 16 and 20 and the active layer 18 are configured as a double heterostructure. For light emission in the wavelength bands of visible to infrared light, these semiconductor layers are made of InGaAIP-based or AlGaAs-based materials. The substrate 22 can be a GaP, GaAs, or other substrate.

On the other hand, for light emission in the wavelength bands of ultraviolet to blue light, the double heterostructure is made of GaN-based materials.

As shown in FIG. 2B, a contact layer 13 made of GaAs and the like, for example, may be provided under the top electrode 10 in order to form an ohmic contact therebetween. Further, as shown in FIG. 2C, a contact layer 13 made of GaAs and the like, for example, may be provided on the whole surface of the current diffusion layer 14, in order to form an ohmic contact therebetween.

When an InGaAIP layer is used for the current diffusion layer 14, its refractive index is about 3.3. The epoxy-based sealing resin 26, having a refractive index of about 1.5, causes a large difference of refractive index. This results in high reflectance at its interface, and total reflection is more likely to occur, thus preventing improvement of the external extraction efficiency. However, in this example, an aluminum nitride (AIN) layer 12 having asperities is provided on top of the current diffusion layer 14 outside the region where the top electrode 10 is provided. Preferably, the asperities of the aluminum nitride layer 12 have a pitch of not more than half the in-medium wavelength of aluminum nitride for light emitted from the active layer 18, and have a height of 500 nm or more. Note that the in-medium wavelength is given by (free space wavelength)/(refractive index). Here, the refractive index of aluminum nitride is about 2.0.

When the asperities of the aluminum nitride layer 12 have a pitch of not more than half the in-medium wavelength, the law no longer holds that light is a light flux traveling in a straight line in accordance with geometrical optics, but wave optics involving diffraction is required for addressing this situation. In particular, when the asperity pitch is sufficiently smaller than the wavelength, the wave nature is further enhanced. As a result, Snell's law does not hold in individual regions of asperities, but it is rather reasonable to treat reflection and transmission of emitted light by assuming that the region is filled with a medium having a refractive index that effectively and continuously varies between the epoxy-based sealing resin 26 and the aluminum nitride layer 12. In fact, an approach based on the effective refractive index is preferred because it is extremely difficult to perform an exact calculation on diffraction phenomena associated with the wave nature in terms of electromagnetism.

Furthermore, as described later in detail, the height of asperities is preferably set to 500 nm or more in order that the asperities of the aluminum nitride layer 12 have a pitch of not more than half the in-medium wavelength.

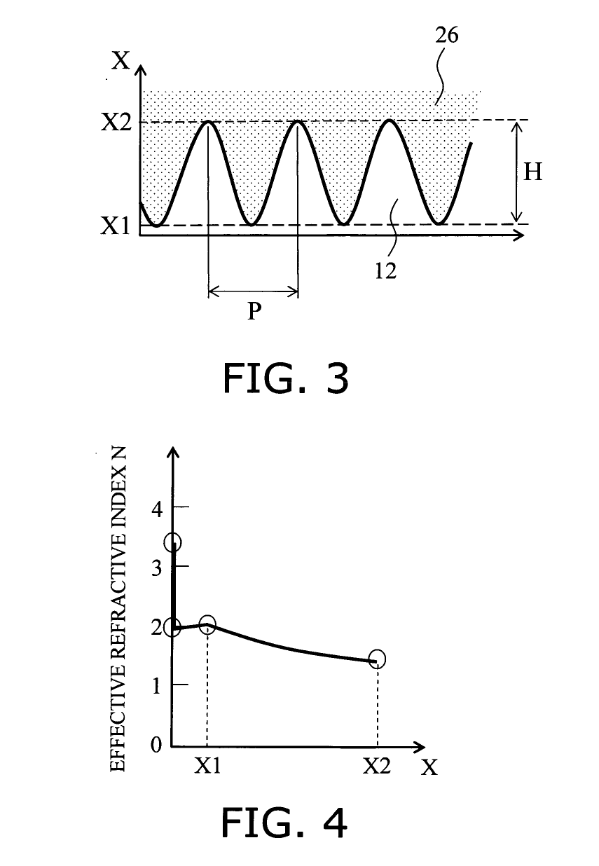

FIG. 3 is an enlarged cross section of the aluminum nitride layer 12.

The aluminum nitride layer 12 is shaped as asperities having a pitch P and a height H, which are filled with an epoxy-based sealing resin 26 from above. The vertical axis X represents the upward distance from the origin located at the boundary between the current diffusion layer 14 and AIN. As described above, preferably, the asperities have a height H of 500 nm or more and a pitch P of not more than half the wavelength.

In the case of this LED 5, light emitted from the active layer 18 passes through the current diffusion layer 14 and is incident on AIN. For an emission wavelength of 660 nm and assuming that the medium is AIN with a refractive index of 2.0, the in-medium wavelength is 660 nm/2.0=330 nm. Therefore, it is preferred to set the pitch P to 165 nm or less.

Thus, in this example, the pitch P is determined by taking into consideration the emission wavelength and the refractive index of the medium. As described later in detail, the layer thickness and the film formation condition for the aluminum nitride layer 12 are determined so that the average crystal grain diameter obtained is comparable to this pitch P.

FIG. 4 is a graphical diagram illustrating the relation of the effective refractive index N to the distance X.

In the figure, X=0 refers to the boundary between the current diffusion layer 14 and the aluminum nitride layer 12. More specifically, X=0 denotes the boundary where the refractive index changes from the refractive index 3.3 of InGaAIP constituting the current diffusion layer 14 to the refractive index 2.0 of AIN. However, reflection is low at X=0 because the refractive index difference is smaller relative to the case where the current diffusion layer 14 is in contact with the epoxy-based sealing resin 26.

On the other hand, the effective refractive index N is 1.5 at X=X2, and continuously varies between 2.0 and 1.5 as a function of X in the range of X1 to X2. The refractive index difference is as small as 0.5 at X=X2, where reflection is therefore very low. The region of X1 to X2 is a region where the reflectance is not determined by geometrical optics from the shape of individual asperities because light behaves in accordance with wave optics. That is, it is reasonable to regard this region as a graded index region because of the continuous variation of refractive index.

As a result, the reflectance is reduced, and thereby the external light extraction efficiency is improved. For comparison, a semiconductor laser is taken for illustration. In a semiconductor laser, the reflectance can be reduced by providing a dielectric between its light emitting layer and the external space, the dielectric having an intermediate refractive index.

In general, for edge emission from a semiconductor laser, the reflectance R at the interface is given by the following equation:
R=(N_{E2}−N_{E1})²/(N_{E2}+N_{E1})² (1)
where N_{E2} is the equivalent refractive index of the semiconductor laser, and N_{E1} is the equivalent refractive index of the external dielectric.

Equation (1) means that reflection depends on the refractive index difference squared. Therefore, the overall reflectance can be reduced by providing a dielectric film having an intermediate refractive index. For example, a semiconductor laser emitting coherent plane waves perpendicularly from its edge into the external space of air typically has a reflectance of about 30%. In contrast, the reflectance can be reduced to about 10% by interposing SiO₂ having a size of about a quarter wavelength

On the other hand, an LED emits incoherent light, which is emitted at a wide range of angles. Therefore, as with the semiconductor laser, the reflectance can be reduced by providing an intermediate refractive index layer, although quantitative estimation is difficult.

In the first example, the reflectance is reduced in accordance with the effective refractive index of the graded index type as illustrated in FIG. 4. At the same time, total reflection can be significantly reduced because it can be assumed that a uniform medium is stuffed. Therefore the external light extraction efficiency is improved.

Next, a method of manufacturing a semiconductor light emitting apparatus of this example is described.

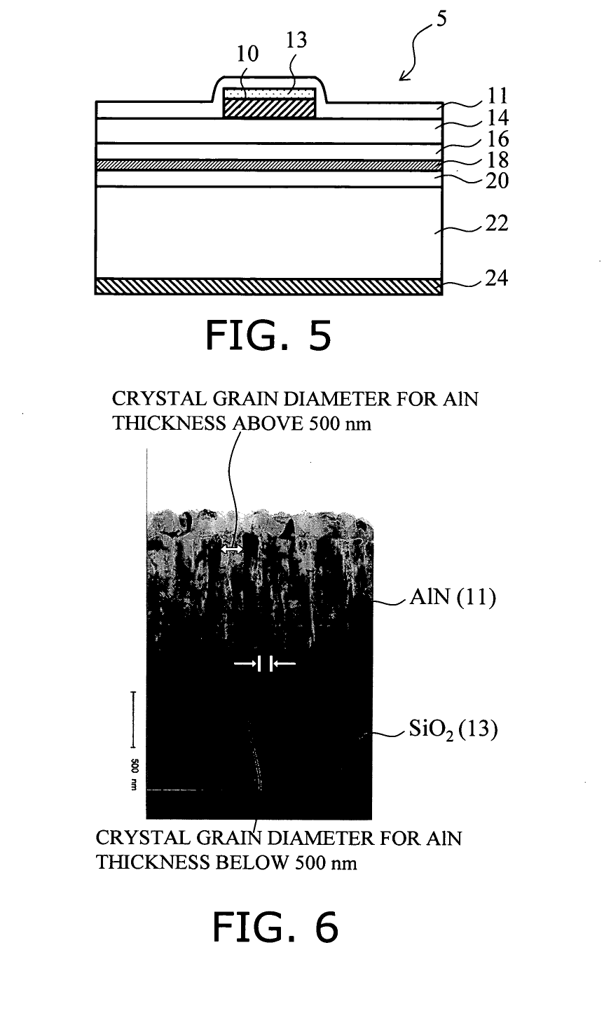

FIGS. 5 to 8 are process cross sections and cross-sectional photographs illustrating the relevant part of a process of manufacturing a semiconductor light emitting apparatus of this example. Here, an InGaAIP-based semiconductor light emitting apparatus for visible light is taken for illustration.

First, as illustrated in FIG. 5, on a GaAs substrate 22, a cladding layer 20, an active layer 18, a cladding layer 16, and a current diffusion layer 14 are crystal grown in this order. The current diffusion layer 14 is an InGaAIP layer, for example, on which a top electrode 10 is patterned. On the other hand, a bottom electrode 24 is formed on the rear face of the substrate 22. An insulating film 13 of SiO₂, for example, formed on top of the top electrode 10 is convenient for subsequent processes, although it may be omitted.

Furthermore, an aluminum nitride (hereinafter AIN) film 11 is formed on the current diffusion layer 14 and the top electrode 10 (on which an insulating film 13 may be provided) by such methods as sputtering or CVD. In this situation, AIN, being hexagonal, is formed as a columnar polycrystal oriented so that their crystalline axes perpendicular to the major surface of the substrate are c-axis. Upon investigation by the inventor, when the film thickness of the AIN film 11 is 500 nm or less, the average crystal grain diameter is as small as 50 nm or less. This tendency does not significantly depend on the deposition condition. This is presumably because the melting point of AIN as high as about 3000° C. prevents migration in the growth process. When the film thickness of the AIN film 11 is 500 nm or more, the crystal grain diameter increases with crystal growth in the c-axis direction. The crystal grain diameter can be increased to about 100 nm, with the average grain diameter being 50 nm or more.

FIG. 6 is a TEM (transmission electron microscopy) photograph showing an example cross section of the AIN film 11 after being formed.

An example growth condition for the AIN film 11 in the case of radio-frequency sputtering is as follows: Ar/N₂ flow rate=15 sccm/100 sccm, RF power=5 kW, pressure=3.3 mPa, and substrate temperature=200° C. It is understood that the grain diameter is about 100 nm since the film thickness is as large as 500 nm or more.

Next, as shown in FIG. 7, the AIN film 11 is etched to form an asperity-like AIN layer 12.

More specifically, the grain boundary of the AIN film 11 can be selectively etched to form an asperity-like AIN layer 12. Selective etching along the crystal grain boundary of AIN can be performed by RIE (reactive ion etching) under the etching condition that the gas flow rate ratio of Cl₂ to BCl₃ is Cl₂/BCl₃>0.5. In this way, AIN can be processed to have a graded index by selectively etching the crystal grain boundary.

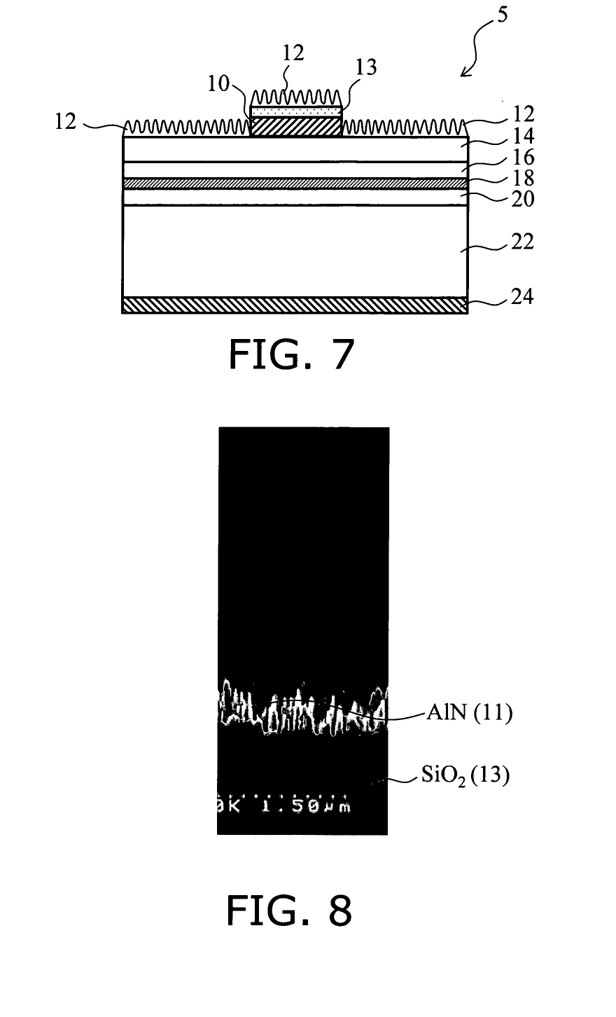

FIG. 8 is a SEM (scanning electron microscopy) photograph showing an example cross section of the AIN layer 12 after RIE.

An example etching condition in the case of RIE method can be as follows: Cl₂/BCl₃ flow rate=60 sccm/19 sccm, RF power=200 W, and pressure=20 mTorr (15 Pa). By performing etching in this condition, etching proceeds along the grain boundary of the AIN film 11. As a result, the average pitch P of asperities of the AIN layer 12 formed by etching has a size corresponding to the crystal grain diameter. As shown in FIG. 8, the pitch P of the asperities has an average of about 100 nm. When the asperities are formed from AIN having a refractive index of about 2.0, the average pitch of asperities of 100 nm corresponds to about 0.3 times the emission wavelength of 660 nm of a red LED. It is understood that such fine asperities formed in the AIN layer 12 can be treated in accordance with wave optics rather than geometrical optics, that is, it can be regarded equivalent to a uniform medium having an effective refractive index. In this case, the in-medium wavelength is about 440 nm in the epoxy resin region of X>X2 (see FIG. 3), which means that the average pitch corresponds to about 0.23 times the in-medium wavelength.

Note that CDE (chemical dry etching) or alkali-based wet etching can also be used instead of RIE to selectively etch the crystal grain boundary.

Subsequently, the LED 5 illustrated in FIG. 2A is completed by removing the insulating film 13 and the AIN layer 12 on the insulating film 13. Even without the insulating film 13, AIN on the electrode can be almost removed by selective etching. However, if the insulating film (e.g., SiO₂) 13 is provided on the top electrode 10, AIN on the electrode is completely removed in the process of removing the insulating film 13, which further facilitates bonding and the like.

Next, the LED 5 is installed in a package.

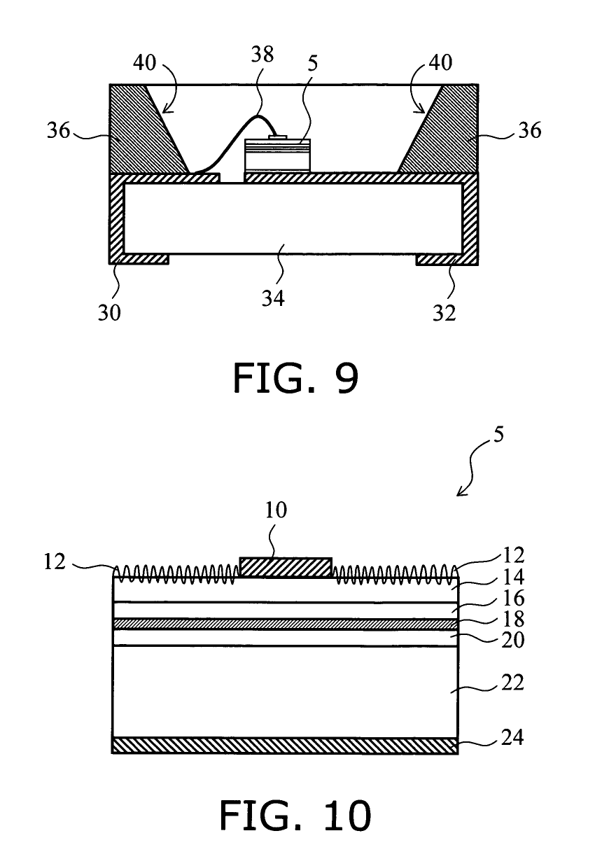

FIG. 9 is a cross section showing the LED 5 being mounted in a package.

The LED 5 is mounted on a first lead 32 with an adhesive such as gold-tin (AuSn) or other metal eutectic solder (not shown) or silver paste. Furthermore, the LED 5 is connected to a second lead 30 via a bonding wire 38. The LED 5 and the bonding wire 38 are then sealed with a sealing resin 26. In this way, the semiconductor light emitting apparatus illustrated in FIG. 1 is completed.

In addition to the method described above, other processes for forming an asperity-like AIN layer 12 may be contemplated. For example, there is a method of processing an AIN layer by using a fine patterned mask created by delineation with light or electron beams (EB). However, this fine patterning process has disadvantages in productivity and cost because it is based on a sophisticated photolithography technology.

On the other hand, there is another process based on block copolymers. More specifically, the phenomenon of interphase separation between the polystyrene (PS) phase and the polymethylene methacrylate (PMMA) phase can be used to form a fine mask. However, this method requires heat treatment for long periods of time for interphase separation. Furthermore, it is not easy to control the size and pitch of the mask. That is, it has disadvantages in throughput and productivity.

However, in the present example, fine asperities of not more than half the wavelength can be formed by a highly productive manufacturing device based on such technologies as sputtering and RIE without any sophisticated photolithography or interphase separation technology in a short period of processing time. The process of this example is superior in process controllability and reproducibility, which allows the semiconductor light emitting apparatus to have uniform characteristics. Furthermore, it is also superior in productivity because it does not need any sophisticated photolithography technology.

While FIGS. 2 and 7 illustrate the structure in which an asperity-like AIN layer 12 is provided only on the upper face of the LED 5, the invention is not limited thereto. For example, the asperity-like AIN layer 12 can be provided also on the side face of the LED 5. This can also improve the light extraction efficiency at the side face of the LED 5.

Next, a second example of the invention is described.

FIG. 10 is a schematic view showing a cross-sectional structure of an LED in a second example of the invention.

In this example, the AIN layer 12 and the directly underlying surface layer of the current diffusion layer 14 are shaped as asperities. This structure is obtained as follows. In the etching process of the first example described above with reference to FIG. 7, after the AIN film is etched to form asperities, etching is further continued to partially transfer the asperities to the underlying current diffusion layer 14. That is, etching of the AIN film is continued to expose the current diffusion layer 14 between adjacent protrusions. Subsequently, the protruding AIN layer 12 is used as an etching mask to etch the surface of the current diffusion layer 14. This etching can be performed by RIE, for example.

In this example, since it is important to partially transfer the asperity configuration of the AIN layer 12 to the current diffusion layer 14, the etching selection ratio of the AIN layer 12 and the current diffusion layer 14 is preferably close to unity. BCl₃ and Ar gas, or SiCl₄ and Ar gas, for example, can be used to perform etching by RIE when the current diffusion layer 14 is made of InGaAIP. By means of such etching, the current diffusion layer 14 and the AIN layer 12 is provided with asperities having nearly uniform pitch P and height H.

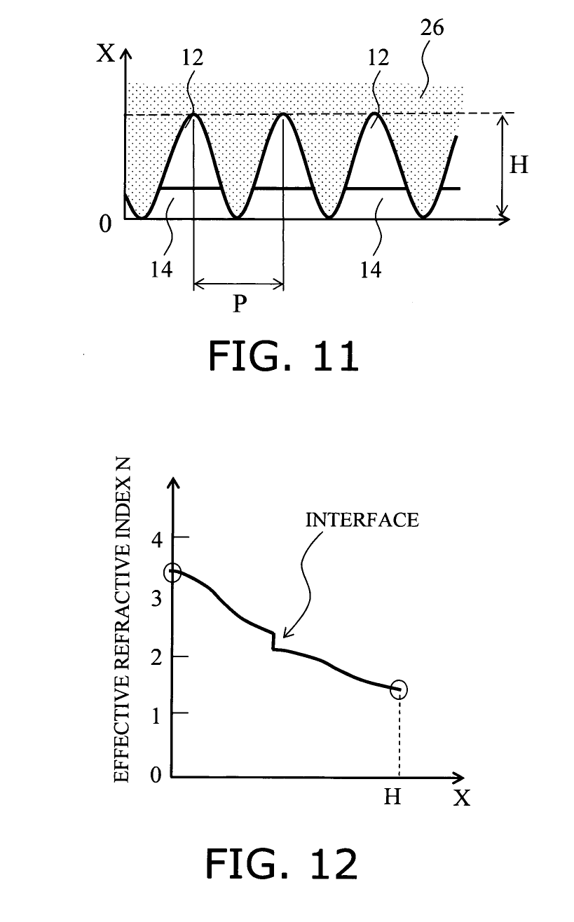

FIG. 11 is a schematic view illustrating asperities formed in the current diffusion layer 14 and the AIN layer 12, and FIG. 12 is a graphical diagram illustrating the variation of effective refractive index in the asperity portion. In FIGS. 11 and 12, X=0 corresponds to the bottom of the asperities.

In this example, the lower portion of the asperities has a graded index structure of the InGaAIP layer having a refractive index of 3.3 and the sealing resin 26 having a refractive index of 1.5. The upper portion of the asperities has a graded index structure of the AIN layer 12 having a refractive index of 2.0 and the sealing resin 26 having a refractive index of 1.5. At the interface between these two different graded index structures, that is, at the interface between the current diffusion layer 14 and the AIN layer 12, the refractive index varies discontinuously. However, since this variation is relatively small, the increase of reflectance can also be limited to a relatively small extent.

As described above, in this example, the asperities of the AIN layer 12 can be partially transferred to the current diffusion layer 14 to form a graded index structure, thereby improving the light extraction efficiency.

Note that in this example, the pitch of the asperities is preferably not more than half the InGaAIP in-medium wavelength. This is because InGaAIP has the largest refractive index and hence the shortest in-medium wavelength among InGaAIP, AIN, and the sealing resin. For an emission wavelength of 660 nm and assuming that the medium is InGaAIP with a refractive index of 3.3, the in-medium wavelength is 660 nm/3.3=200 nm. Therefore, it is preferred to set the asperity pitch P to 100 nm or less.

While the current diffusion layer 14 provided as an upper layer of the semiconductor multilayer structure is made of InGaAIP and the like, a contact layer made of GaAs and the like, for example, may be provided between the current diffusion layer 14 and the top electrode 10 in order to form an ohmic contact therebetween. In this case, the asperities may be formed in the contact layer instead of the current diffusion layer 14, or the asperities may be formed both in the contact layer and the current diffusion layer 14.

While FIG. 10 illustrates the structure in which asperities of the AIN layer 12 and the current diffusion layer 14 are provided only on the upper face of the LED, the invention is not limited thereto. For example, such asperities can be provided also on the side face of the LED. More specifically, similar asperities can be formed also on the side face of the LED by forming an AIN film on the side face of the LED, etching the AIN film into asperities, and further continuing etching to partially transfer the asperities to the underlying semiconductor layer. This can also improve the light extraction efficiency at the side face of the LED.

Next, a third example of the invention is described.

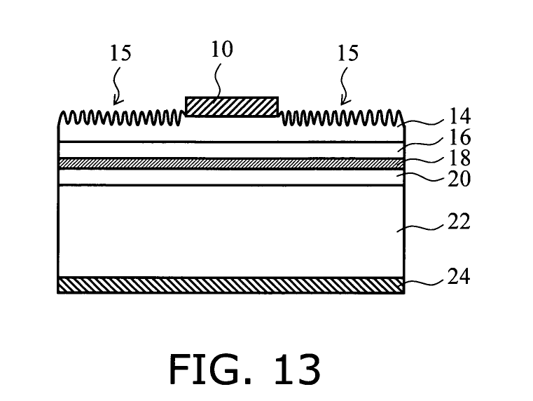

FIG. 13 is a schematic view showing a cross-sectional structure of an LED in a third example of the invention.

In this example, the surface layer of the current diffusion layer 14 is shaped as asperities. This asperity structure 15 is obtained as follows. In the etching process of the first example described above with reference to FIG. 7, after the AIN film is etched to form asperities, etching is further continued to completely transfer the asperities to the underlying current diffusion layer 14.

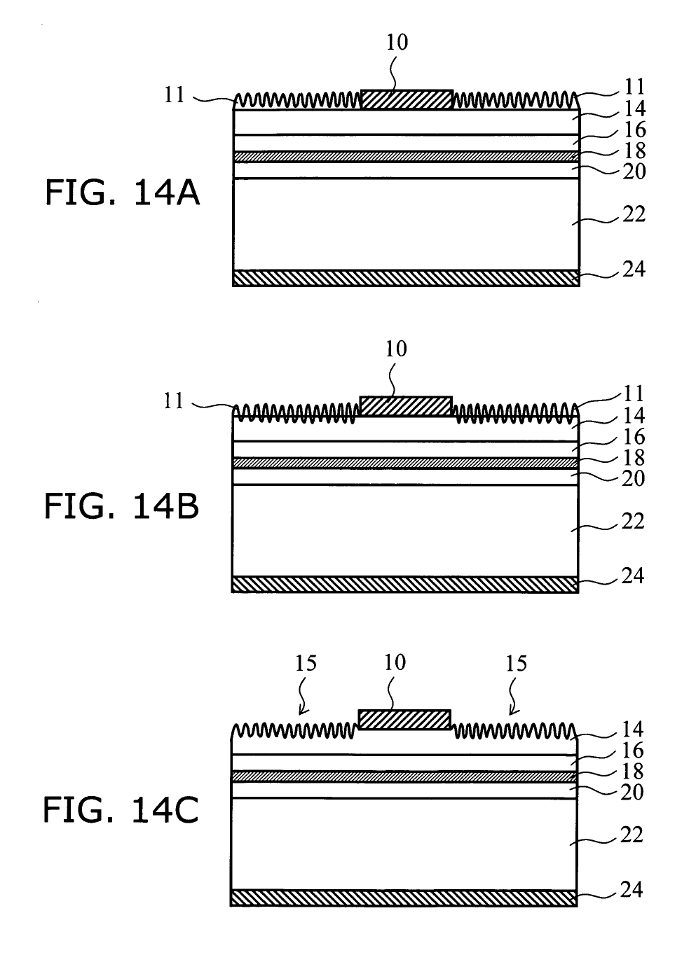

FIG. 14 is a process cross section illustrating part of a process of manufacturing an LED in this example.

More specifically, as shown in FIG. 14A, the AIN film 11 is etched to form asperities corresponding to columnar crystal. As shown in FIG. 14B, etching is further continued to expose the current diffusion layer 14 between adjacent protrusions, and the protruding AIN layer 12 is used as an etching mask to etch the surface of the current diffusion layer 14. Etching is further continued until the residual protruding AIN layer 12 is removed. In this way, as shown in FIG. 14C, the asperity configuration of the AIN layer 12 can be completely transferred to the underlying current diffusion layer 14. This etching can be performed by RIE, for example.

In this example as well, since it is important to transfer the asperity configuration of the AIN layer 12 to the current diffusion layer 14, the etching selection ratio of the AIN layer 12 and the current diffusion layer 14 is preferably close to unity. BCl₃ and Ar gas, or SiCl₄ and Ar gas, for example, can be used to perform etching by RIE when the current diffusion layer 14 is made of InGaAIP. By means of such etching, the asperities formed in the AIN layer 12 is transferred to the current diffusion layer 14, which is thus provided with asperities having nearly uniform pitch P and height H.

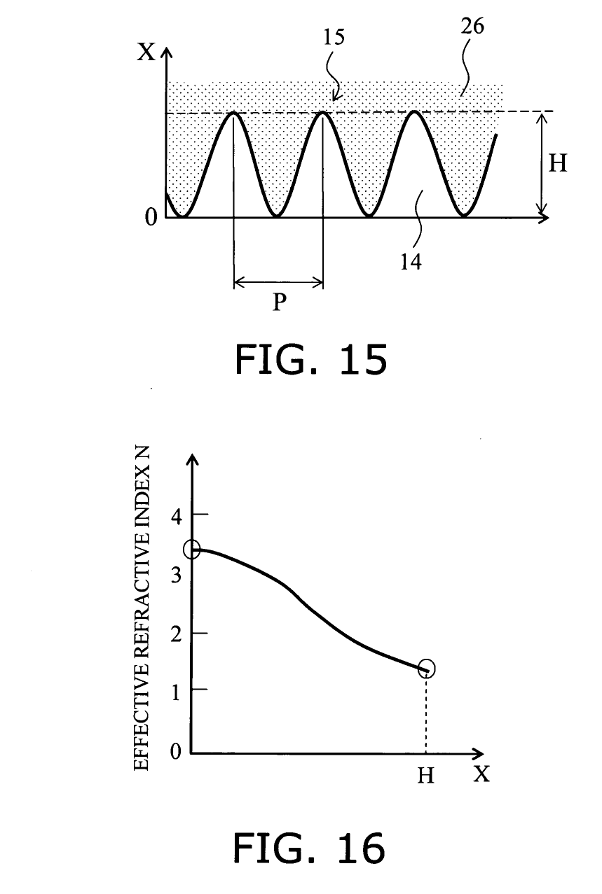

FIG. 15 is a schematic view illustrating asperities formed in the current diffusion layer 14, and FIG. 16 is a graphical diagram illustrating the variation of effective refractive index in the asperity portion. In FIGS. 15 and 16 as well, X=0 corresponds to the bottom of the asperities.

In this example, the portion of asperities has a graded index structure of the InGaAIP layer having a refractive index of 3.3 and the sealing resin 26 having a refractive index of 1.5.

In the case where the current diffusion layer 14 is made of InGaAIP having a refractive index of 3.3, light emission having a wavelength of 660 nm has an in-medium wavelength of 200 nm. When the asperities have an average pitch of 100 nm as illustrated in FIG. 8, it corresponds to about 0.5 times the in-medium wavelength. In an epoxy resin having a refractive index of 1.5, the asperity pitch of 100 nm corresponds to about 0.23 times the in-medium wavelength.

As shown in FIG. 16, the effective refractive index is equal to the refractive index 3.3 of InGaAIP at the lowermost part of the asperities and equal to the refractive index 1.5 of the resin at the uppermost part of the asperities, and varies continuously with distance X in the range of 0 to H. That is, a graded index structure is obtained. The way of variation of the effective refractive index depends on the configuration of the asperities. This smooth variation of refractive index allows for reducing the reflectance for light emission from the LED, which leads to a high light extraction efficiency.

According to prototyping by the inventor, the light extraction efficiency was improved by about 14% as a result of providing an asperity configuration on the surface of the current diffusion layer 14 made of InGaAIP. It is contemplated that this improvement is primarily attributed to reduction of reflectance.

Note that in this example as well, the pitch of the asperities is preferably not more than half the InGaAIP in-medium wavelength. Therefore, as described above in connection with the second example, it is preferred to set the asperity pitch P to 100 nm or less.

While the current diffusion layer 14 provided as an upper layer of the semiconductor multilayer structure is made of InGaAIP and the like, a contact layer made of GaAs and the like, for example, may be provided between the current diffusion layer 14 and the top electrode 10 in order to form an ohmic contact therebetween. In this case, the asperities may be formed in the contact layer instead of the current diffusion layer 14, or the asperities may be formed both in the contact layer and the current diffusion layer 14.

While FIG. 13 illustrates the structure in which asperities are provided only on the surface of the current diffusion layer 14, the invention is not limited thereto. For example, such asperities can be provided also on the side face of the LED. More specifically, similar asperities can be formed also on the side face of the LED by forming an AIN film on the side face of the LED, etching the AIN film into asperities, and further continuing etching to completely transfer the asperities to the underlying semiconductor layer. This can also improve the light extraction efficiency at the side face of the LED.

Embodiments of the invention have been described with reference to examples. However, the invention is not limited to these examples.

For example, the invention is not limited to the use of InGaAIP-based compound semiconductors for the LED. GaN-based, GaAIAs-based, and other compound semiconductors may be used.

The light emitted from the LED is not limited to visible light, but may include ultraviolet light. For example, ultraviolet or blue light can be used in combination with phosphors dispersed in the sealing resin to perform wavelength conversion for obtaining white light.

Any configuration, size, material, and arrangement of various elements including the LED, sealing resin, and AIN composing the semiconductor light emitting apparatus that are variously adapted by those skilled in the art are also encompassed within the scope of the invention as long as they include the features of the invention.

1. A semiconductor light emitting device comprising:
a semiconductor multilayer structure including a light emitting layer that emits a light; and
an aluminum nitride layer provided on a surface of the semiconductor multilayer structure, the aluminum nitride layer having asperities with an average pitch of not more than half an in-medium wavelength of the light in aluminum nitride.

2. A semiconductor light emitting device according to claim 1, wherein the semiconductor multilayer structure includes at least one of InGaAIP-based, GaAIAs-based, and GaN-based materials.

3. A semiconductor light emitting device according to claim 1, wherein the semiconductor multilayer structure further includes a contact layer on the surface thereof, and an electrode forming an ohmic contact with the contact layer is further provided on the surface of the semiconductor multilayer structure outside a region where the aluminum nitride layer is provided.

4. A semiconductor light emitting device according to claim 1, wherein the asperities have an average height difference of 500 nanometers or more.

5. A semiconductor light emitting device according to claim 1, wherein the aluminum nitride layer has an average grain diameter of 50 nanometers or more.

6. A semiconductor light emitting device according to claim 1, wherein the aluminum nitride layer is a columnar polycrystal oriented so that their crystalline axes perpendicular to said surface are c-axis.

7. A semiconductor light emitting device comprising:
a semiconductor multilayer structure including a light emitting layer that emits light; and
an aluminum nitride layer provided on a surface of the semiconductor multilayer structure,
the semiconductor light emitting device having asperities composed of a plurality of protrusions including the aluminum nitride layer and a plurality of depressions intruding into the semiconductor multilayer structure.

8. A semiconductor light emitting device according to claim 7, wherein the semiconductor multilayer structure includes at least one of InGaAIP-based, GaAIAs-based, and GaN-based materials.

9. A semiconductor light emitting device according to claim 7, wherein the semiconductor multilayer structure further includes a contact layer on the surface thereof, and an electrode forming an ohmic contact with the contact layer is further provided on the surface of the semiconductor multilayer structure outside a region where the aluminum nitride layer is provided.

10. A semiconductor light emitting device according to claim 7, wherein an average pitch of the asperities is not more than half an in-medium wavelength of the light in a semiconductor part at the surface of the semiconductor multilayer structure.

11. A semiconductor light emitting device according to claim 7, wherein the asperities have an average height difference of 500 nanometers or more.

12. A semiconductor light emitting device according to claim 7, wherein the aluminum nitride layer is a columnar polycrystal oriented so that their crystalline axes perpendicular to said surface are c-axis.

13. A semiconductor light emitting apparatus comprising:
a packaging member;
a semiconductor light emitting device mounted on the packaging member; and
a sealing resin sealing the semiconductor light emitting device,
the semiconductor light emitting device having:
a semiconductor multilayer structure including a light emitting layer that emits a light; and
an aluminum nitride layer provided on a surface of the semiconductor multilayer structure, the aluminum nitride layer having asperities with an average pitch of not more than half an in-medium wavelength of the light in aluminum nitride,
or
the semiconductor light emitting device having:
a semiconductor multilayer structure including a light emitting layer that emits light; and
an aluminum nitride layer provided on a surface of the semiconductor multilayer structure,
the semiconductor light emitting device having asperities composed of a plurality of protrusions including the aluminum nitride layer and a plurality of depressions intruding into the semiconductor multilayer structure.

14. A semiconductor light emitting apparatus according to claim 13 wherein the semiconductor light emitting device having formed by:
forming a polycrystalline aluminum nitride layer on a surface of a semiconductor multilayer structure including a light emitting layer; and
etching the aluminum nitride layer to form asperities that generally correspond to distribution of crystal grains constituting the polycrystal.

15. A method of manufacturing a semiconductor light emitting device comprising:
forming a polycrystalline aluminum nitride layer on a surface of a semiconductor multilayer structure including a light emitting layer; and
etching the aluminum nitride layer to form asperities that generally correspond to distribution of crystal grains constituting the polycrystal.

16. A method of manufacturing a semiconductor light emitting device according to claim 15, wherein the asperities are formed inside the aluminum nitride layer.

17. A method of manufacturing a semiconductor light emitting device according to claim 15, wherein the asperities are formed in the aluminum nitride layer and in the semiconductor multilayer structure.

18. A method of manufacturing a semiconductor light emitting device according to claim 15, wherein the aluminum nitride layer is etched off and thereby the asperities are formed in the semiconductor multilayer structure.

19. A method of manufacturing a semiconductor light emitting device according to claim 15, wherein the polycrystalline aluminum nitride layer is formed oriented so that their crystalline axes perpendicular to said surface are c-axis.

20. A method of manufacturing a semiconductor light emitting device according to claim 15, wherein the asperities are formed by reactive ion etching with a gas containing chlorine.
